(19) United States
(12) Patent Application Publication
(10) Pub. No.: US 2007/0295399 A1
(43) Pub. Date: Dec. 27, 2007

(54) Back-Contact Photovoltaic Cells

(75) Inventor: David E. Carlson, Williamsburg, VA (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 11/763,090

(22) Filed: Jun. 14, 2007

Related U.S. Application Data
(63) Continuation-in-part of application No. 11/565,738, filed on Dec. 1, 2006.
(60) Provisional application No. 60/751,168, filed on Dec. 16, 2005.

(51) Int. Cl. H01L 31/00

(52) U.S. Cl. 136/261; 427/74

(57) ABSTRACT

A photovoltaic cell comprising a wafer comprising a semiconductor material of a first conductivity type, the wafer comprising a first light receiving surface and a second surface opposite the first surface; a first passivation layer positioned over the first surface of the wafer; a first electrical contact comprising point contacts positioned over the second surface of the wafer and having a conductivity type opposite to that of the wafer; and a second electrical contact comprising point contacts and positioned over the second surface of the wafer and separated electrically from the first electrical contact and having a conductivity type the same as that of the wafer.

This is a continuation-in-part application of U.S. patent application Ser. No. 11/565,738, filed on Dec. 1, 2006, which claims the benefit of U.S. Provisional Patent Application 60/751,168, filed on Dec. 16, 2005.

### BACKGROUND OF THE INVENTION

This invention relates to new photovoltaic cells. More particularly, this invention relates to photovoltaic cells that are highly efficient in converting light energy, and particularly solar energy, to electrical energy and where such cells have electrical contacts on the back surface. This invention is also a process for making such cells.

One of the most important features of a photovoltaic cell is its efficiency in converting light energy from the sun into electrical energy. Another important feature is the ability to manufacture such cell in a manner applicable to large-scale manufacturing processes. Thus, the art is continuously striving to not only improve the efficiency of photovoltaic cells in converting light energy into electrical energy, but also to manufacture them using safe, environmentally compatible, large-scale manufacturing processes.

Although photovoltaic cells can be fabricated from a variety of semiconductor materials, silicon is generally used because it is readily available at reasonable cost and because it has the proper balance of electrical, physical and chemical properties for use in fabricating photovoltaic cells. In a typical procedure for the manufacture of photovoltaic cells using silicon as the selected semiconductor material, the silicon is doped with a dopant of either positive or negative conductivity type, formed into either ingots of monocrystalline silicon, or cast into blocks or “bricks” of what the art refers to as a multicrystalline silicon, and these ingots or blocks are cut into thin substrates, also referred to as wafers, by various slicing or sawing methods known in the art. These wafers are used to manufacture photovoltaic cells. However, these are not the only methods used to obtain suitable semiconductor wafers for the manufacture of photovoltaic cells.

By convention, positive conductivity type is commonly designated as “p” or “p-type” and negative conductivity type is designated as “n” or “n-type”. Therefore, “p” and “n” are opposing conductivity types.

The surface of the wafer intended to face incident light when the wafer is formed into a photovoltaic cell is referred to herein as the front face or front surface, and the surface of the wafer opposite the front face is referred to herein as the back face or back surface.

In a typical and general process for preparing a photovoltaic cell using, for example, a p-type silicon wafer, the wafer is exposed to a suitable n-dopant to form an emitter layer and a p-n junction on the front, or light-receiving side of the wafer. Typically, the n-type layer or emitter layer is formed by first depositing the n-dopant onto the front surface of the p-type wafer using techniques commonly employed in the art such as chemical or physical deposition and, after such deposition, the n-dopant, for example, phosphorus, is driven into the front surface of the silicon wafer to further diffuse the n-dopant into the wafer surface. This “drive-in” step is commonly accomplished by exposing the wafer to high temperatures. A p-n junction is thereby formed at the boundary region between the n-type layer and the p-type silicon wafer substrate. The wafer surface, prior to the phosphorus or other doping to form the emitter layer, can be textured.

In order to utilize the electrical potential generated by exposing the p-n junction to light energy, the photovoltaic cell is typically provided with a conductive front electrical contact on the front face of the wafer and a conductive back electrical contact on the back face of the wafer. Such contacts are typically made of one or more highly electrically conducting metals and are, therefore, typically opaque. Since the front contact is on the side of the photovoltaic cell facing the sun or other source of light energy, it is generally desirable for the front contact to take up the least amount of area of the front surface of the cell as possible yet still capture the electrical charges generated by the incident light interacting with the cell. Even though the front contacts are applied to minimize the area of the front surface of the cell covered or shaded by the contact, front contacts nevertheless reduce the amount of surface area of the photovoltaic cell that could otherwise be used for generating electrical energy. The process described above also uses a number of high temperature processing steps to form the photovoltaic cells. Using high temperatures increases the amount of time needed to manufacture photovoltaic cells, consumes energy, and requires the use of expensive high temperature furnaces or other equipment for processing photovoltaic cells at high temperatures.

The art therefore needs photovoltaic cells that have high efficiency, can be manufactured using large scale production methods, and, preferably, by methods that do not utilize high temperature processing steps or, at least, use a minimum of high temperature processing steps, and where the cells, in order to increase efficiency, do not have electrical contacts on the front side or surface of the wafer, thereby maximizing the available area of the front surface of the cell for converting light into electrical current. The present invention provides such a photovoltaic cell. The photovoltaic cells of this invention can be used to efficiently generate electrical energy by exposing the photovoltaic cell to the sun.

### SUMMARY OF THE INVENTION

This invention is a photovoltaic cell comprising a wafer comprising a semiconductor material of a first conductivity type, a first light receiving surface and a second surface opposite the first surface; a first passivation layer positioned over the first surface of the wafer; a first electrical contact comprising point contacts positioned over the second surface of the wafer and having a conductivity opposite to that of the wafer; a second electrical contact comprising point contacts positioned over the second surface of the wafer and separated electrically from the first electrical contact and having a conductivity the same as that of the wafer.

This invention is also a process for manufacturing such a photovoltaic cell.

### BRIEF DESCRIPTION OF THE DRAWING

FIG. 1 is a three-dimensional, partial cut-away view of a portion of a photovoltaic cell in accordance with an embodiment of this invention.

FIG. 2 is a plan view of a portion of the photovoltaic cell of FIG. 1.

FIG. 3 is a cross-sectional view of a portion of a photovoltaic cell of FIG. 1.

FIG. 4 is a diagram of a process in accordance with an embodiment of this invention.

FIG. 5 is a cross-sectional view of a portion of a photovoltaic cell in accordance with an embodiment of this invention.

### DETAILED DESCRIPTION OF THE INVENTION

A semiconductor wafer useful in the process of this invention for preparing photovoltaic cells preferably comprises silicon and is typically in the form of a thin, flat shape. The silicon may comprise one or more additional materials, such as one or more semiconductor materials, for example germanium, if desired. For a p-type wafer, boron is widely used as the p-type dopant, although other p-type dopants, for example, aluminum, gallium or indium, will also suffice. Boron is the preferred p-type dopant. Combinations of such dopants are also suitable. Thus, the dopant for a p-type wafer can comprise, for example, one or more of boron, aluminum, gallium or indium, and preferably it comprises boron. If an n-type silicon wafer is used, the dopants can be, for example, one or more of phosphorus, arsenic, antimony, or bismuth. Suitable wafers are typically obtained by slicing or sawing silicon ingots, such as ingots of monocrystalline silicon, to form monocrystalline wafers, such as the so-called Czochralski (C_{z}) silicon wafers. Suitable wafers can also be made by slicing or sawing blocks of cast, multi-crystalline silicon. Silicon wafers can also be pulled straight from molten silicon using processes such as Edge-defined Film-fed Growth technology (EFG) or similar techniques. Although the wafers can be any shape, wafers are typically circular, square or pseudo-square in shape. “Pseudo-square” means a predominantly square shaped wafer usually with rounded corners. The wafers used in the photovoltaic cells of this invention are suitably thin. For example, wafers useful in this invention can be about 10 microns thick to about 300 microns thick. For example, they can be about 10 microns up to about 200 microns thick. They can be about 10 microns up to about 30 microns thick. If circular, the wafers can have a diameter of about 100 to about 180 millimeters, for example 102 to 178 millimeters. If square or pseudo-square, they can have a width of about 100 millimeters to about 150 millimeters with rounded corners having a diameter of about 127 to about 178 millimeters. The wafers useful in the process of this invention, and consequently the photovoltaic cells made by the process of this invention can, for example, have a surface area of about 100 to about 250 square centimeters. The wafers doped with the first dopant that are useful in the process of this invention can have a resistivity of about 0.1 to about 20 ohm·cm, typically of about 0.5 to about 5.0 ohm·cm.

The wafers used in the photovoltaic cells of this invention preferably have a diffusion length (L) that is greater than the wafer thickness (t). For example, the ratio of L to t is suitably greater than 1. It can, for example be greater than about 1.1, or greater than about 2. The ratio can be up to about 3 or more. The diffusion length is the average distance that minority carriers (such as electrons in p-type material) can diffuse before recombining with the majority carriers (holes in p-type material). The L is related to the minority carrier lifetime τ through the relationship L=(D_{τ})^{1/2} where D is the diffusion constant. The diffusion length can be measured by a number of techniques such as the Photon-Beam-Induced Current technique or the Surface Photovoltage technique. See for example, “Fundamentals of Solar Cells”, by A. Fahrenbruch and R. Bube, Academic Press, 1983, pp. 90-102, which is incorporated by reference herein, for a description of how the diffusion length can be measured.

Although the term wafer, as used herein, includes the wafers obtained by the methods described, particularly by sawing or cutting ingots or blocks of single crystal or multi-crystalline silicon, it is to be understood that the term wafer can also include any other suitable semiconductor substrate or layer useful for preparing photovoltaic cells by the process of this invention.

The front surface of the wafer is preferably textured. Texturing generally increases the efficiency of the resulting photovoltaic cell by increasing light absorption. For example, the wafer can be suitably textured using chemical etching, plasma etching, laser or mechanical scribing. If a monocrystalline wafer is used, the wafer can be etched to form an anisotropically textured surface by treating the wafer in an aqueous solution of a base, such as sodium hydroxide, at an elevated temperature, for example about 70° C. to about 90° C. for about 10 to about 120 minutes. The aqueous solution may contain an alcohol, such as isopropanol. A multicrystalline wafer can be textured by mechanical dicing using beveled dicing blades or profiled texturing wheels. In a preferred process a multicrystalline wafer is textured using a solution of hydrofluoric acid, nitric acid and water. Such a texturing process is described by Hauser, Melnyk, Fath, Narayanan, Roberts and Bruton in their paper “A Simplified Process for Isotropic Texturing of MC—Si”, Hauser, et al., from the conference “3^{rd} World Conference on Photovoltaic Energy Conversion”, May 11-18, Osaka, Japan, which is incorporated by reference herein in its entirety. The textured wafer is typically subsequently cleaned, for example, by immersion in hydrofluoric and then hydrochloric acid with intermediate and final rinsing in de-ionized water, followed by drying. The back surface of the wafer may or may not be textured depending on the thickness of the wafer and the light-trapping geometry employed.

Prior to texturing a wafer, the wafer can be subjected to phosphorus and/or aluminum gettering. For example, gettering can be accomplished by forming a heavily n-doped layer by, for example, phosphorus diffusion on one or both sides of the wafer. This can be accomplished, for example, by exposing the wafer to a gas such as POCl₃, for 30 minutes at 900° C. to 1000° C. Such gettering will increase the diffusion length of the wafer. After formation of the heavily n-doped layer or layers, they can be removed by, for example, etching using acids such as hydrofluoric acid (HF) and nitric acid (HNO₃) or a mixture thereof, or strong bases such as sodium hydroxide (NaOH). One embodiment of this invention would involve forming a heavily n-doped layer on the front of the wafer to getter impurities and then subsequently removing it during the texture etching of the front surface as described above.

In a preferred embodiment of this invention, the photovoltaic cell has a first passivation layer, preferably one that can also function as an anti-reflective coating, on the front surface of the wafer. If the wafer is textured, such layer is preferably added after such texturing. Such first passivation layer can be, for example, a layer of a dielectric such as silicon dioxide, silicon carbide, silicon oxynitride or silicon nitride, which can be formed by methods known in the art such as, for example, plasma enhanced chemical vapor deposition (PECVD), low pressure chemical vapor deposition (LPCVD), thermal oxidation, screen printing of pastes, inks or sol gel, and the like. Combinations of two or more of such layers can also be used to form the first passivation layer such as a layer of silicon nitride and a layer of silicon dioxide. When more than one layer is used, at least one of the layers is, preferably, a passivation layer comprising, for example, silicon nitride. Preferably, the passivation layer comprises a layer of silicon nitride formed directly on the surface of the wafer by a method such as PECVD so that the silicon nitride contains hydrogen. Combinations of two or more layers can be chosen so that the combined layers reduce the reflection of light in the wavelength range of 350 to 1100 nanometers (nm) from the front surface, and the first layer deposited on the silicon surface acts as a passivation layer. The total of all such layers used can be up to about 120 nm in thickness, for example about 70 to about 100 nm in thickness. Hydrogenated silicon nitride can be deposited at temperatures of about 200° C. to about 450° C., for example, about 350° C. to about 400° C., using PECVD in an atmosphere of silane and ammonia.

A suitable first passivation layer can also comprise a layer of hydrogenated amorphous silicon (a-Si:H), a layer of hydrogenated microcrystalline silicon, or a mixture of a-Si:H and hydrogenated microcrystalline silicon, and particularly where such layer is deposited or otherwise formed so it is directly on the wafer. Preferably such layer comprises nitrogen in addition to silicon. Such layer can also comprise boron, with or without nitrogen. In some cases, it may be preferable for such layer to comprise other dopants such as phosphorus or be alloyed with other elements such as carbon, nitrogen or oxygen. If nitrogen is included in the first passivation layer comprising a-Si:H, hydrogenated microcrystalline silicon, or mixtures thereof, the amount or concentration of nitrogen can be graded such that the amount of nitrogen in the layer is at a minimum, for example, no nitrogen, next to the wafer, and reaches a level so that the layer becomes silicon nitride furthest away from the interface with the wafer. Ammonia can be used as a suitable source of nitrogen. If boron or phosphorus is used, the boron or phosphorus concentration can be graded in the same manner where there is no boron or phosphorus next to or nearest to the wafer and reaching a maximum boron or phosphorus concentration up to about 1 atomic percent, based on the total amount of silicon and, if present, nitrogen in the layer. If such layer comprising a-Si:H, hydrogenated microcrystalline silicon, or mixtures thereof is applied, with or without nitrogen, and with or without a dopant such as boron or phosphorus, it can have a thickness of up to about 40 nm. It can, for example, be about 3 to about 30 nm thick. Such a-Si:H layer can be applied by any suitable method such as, for example, by PECVD in an atmosphere of silane. Most suitably, it is applied by PECVD in an atmosphere containing about 10% silane in hydrogen, and most suitably it is applied at low temperatures such as, for example, about 100° C. to about 250° C. Without intending to be bound by a theory of operation, the first passivation layer can function to reduce the wafer surface recombination velocity to <100 cm/s (a low surface recombination velocity <100 cm/s is indicative of a low density of defect states at the surface). The first passivation layer can also contain fixed charges, such as commonly found in silicon nitride layers, whose electric field induces band bending in the region of the semiconductor wafer near the wafer surface. Since the fixed charge in silicon nitride is usually positive, this band bending can act to repel minority carriers from the wafer surface region and can thus also reduce surface recombination if the wafer is n-type. If the wafer is p-type, the positive charge can act to create an inversion layer, and the surface recombination can still be low if the density of defects on the surface is low. Thus, any material that can provide such function of reducing wafer surface recombination and can be applied to the silicon wafer, can be a suitable first passivation layer. Such layer, as described above, can comprise a plurality of layers, some or all of such layers being different materials selected, for example, from the materials described above.

A silicon nitride layer can act both as the first passivation layer and as the anti-reflective layer on the first surface of the wafer with a thickness of up to about 120 nm thick, for example about 70 to about 100 nm in thickness. The silicon nitride can be deposited by PECVD in silane and ammonia at a deposition temperature of about 350° C. to 400° C.

In another embodiment, the nitrogen content of such silicon nitride layer is graded. For example, the nitrogen content can increase from zero at the part of the silicon nitride layer nearest the surface of the silicon wafer to approximately the level found in Si₃N₄ over a thickness of up to about 10 nm and then remains constant over the remaining thickness of the layer, for example, about another 70 nm.

The photovoltaic cells of this invention preferably comprise a second passivation layer on the second, back surface of the wafer preferably comprising a layer of silicon nitride. Preferably, such layer of silicon nitride on the second surface of the wafer is in direct contact with the wafer although a layer comprising a-Si:H, or microcrystalline silicon, or a mixture of a-Si:H and microcrystalline silicon can be positioned between a layer of silicon nitride and the back surface of the wafer. The layer of silicon nitride on the back surface of the wafer can be formed and can have the composition as described above for the layer of silicon nitride on the front surface of the wafer. It can have the same thickness as described for the silicon nitride layer on the first surface of the wafer. Such layer of silicon nitride can be formed in the same process step as when the first layer of silicon nitride is formed on the first surface of the wafer. Such layer of silicon nitride can contain a dopant such as antimony, phosphorus or a combination thereof. If such dopant is present, it can be about 0.1 to about 1.0 atomic percent of the silicon nitride layer. A layer comprising a-Si:H, or microcrystalline silicon, or a mixture of a-Si:H and microcrystalline silicon, if positioned between a layer of silicon nitride and the back surface of the wafer, or if used without a silicon nitride layer as the second passivation layer, can be formed and can have the same composition as described above for the passivation layers on the first surface of the wafer.

The back or second surface of the wafer in the photovoltaic cells of this invention comprises two electrical contacts, preferably each comprises one or more metals. One of the contacts can comprise a metal, or a metal containing another metal, that can function as an n-type dopant in silicon. For example, the metal can be tin which is isoelectronic with silicon, or tin alloyed with phosphorus, arsenic, antimony, bismuth or a combination thereof. If tin is used and, for example, it is alloyed with an element such as antimony, the amount of such alloy element can be about 0.1 to about 20 atomic percent. Such contact can be deposited initially as a layer by any suitable means, such as, for example, sputtering a suitable target using a magnetron sputtering apparatus. Such electrical contacts preferably comprise point contacts, and more preferably point contacts that are formed by a laser firing process. The n-type contact may be formed by first depositing a thin layer of antimony, for example, about 10 to about 200 nm in thickness, and then a thicker layer of tin, for example, about 500 to about 10,000 nm in thickness on top of the second passivation layer, for example, about 700 nm of silicon nitride, before forming the point contact to the silicon wafer using, for example, a laser firing process. The tin and antimony layers may be deposited, for example, by sputtering, thermal evaporation or electron-beam evaporation. Another embodiment would be to co-sputter, or co-evaporate, the tin and antimony onto a second passivation layer, such as one made of silicon nitride, at the same time so as to deposit an alloy of tin and antimony, for example, about 5 atomic percent antimony in tin, with a total layer thickness of about 0.5 to about 10 microns. The other contact can comprise a metal, or a metal containing another metal, that can function as a p-conductivity dopant in silicon, for example, aluminum or indium. Another embodiment would be to use a tin alloy containing 0.1 to 20 atomic percent of a p-type dopant such as one or more of boron, aluminum, gallium or indium. Such contacts can be deposited initially as a layer by any suitable means, such as, for example, sputtering a suitable target using a magnetron sputtering apparatus. Such electrical contacts preferably comprise point contacts, and more preferably point contacts that are formed by a laser firing process. Such point contacts and a laser firing process to form them will be described in more detail below.

The first contact and the second contact are electrically separated from each other by, for example, a layer of a suitable insulation material such as one or more of silicon nitride, silicon oxide or silicon oxynitride. When silicon nitride is used for such insulation layer, it can have the same composition as described above for the other layers of silicon nitride and can be formed by the same processes. The insulation layer should be formed so that it is free or substantially free of pinholes, and should be sufficiently thick so that there is no dielectric breakdown of the layer during operation of the photovoltaic cell. Such layer can be up to about 1 micron in thickness, for example, about 0.1 to about 1 micron in thickness. As described above, the electrical contacts in the photovoltaic cell of this invention are mainly, and preferably only, on the back surface of the wafer and therefore do not shade or obstruct the front, light-receiving surface of the wafer. This results in a photovoltaic cell that is more efficient in converting light energy to electrical energy.

Certain embodiments of the invention will now be described with respect to the Figures. The Figures are not necessarily drawn to scale. For example, the thickness of the various metals, semiconductor and other layers shown in the Figures are not necessarily in scale with respect to each other.

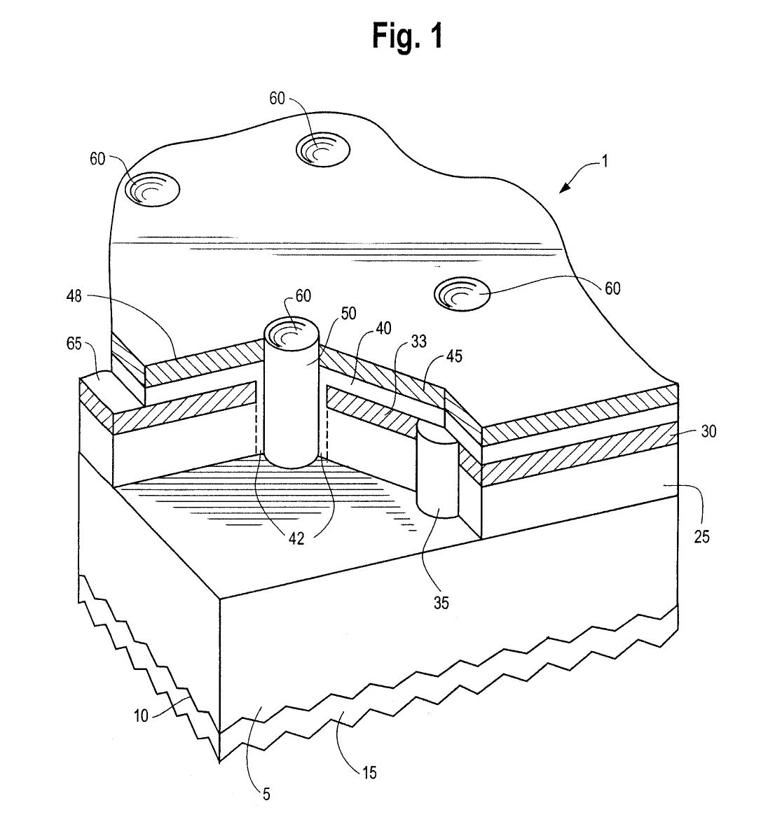

FIG. 1 shows a three-dimensional, partial cut away view of a part of photovoltaic cell 1 in accordance with an embodiment of this invention. The back surface of the cell is facing up in FIG. 1. Photovoltaic cell 1 has a wafer 5 of p-type crystalline silicon. Front or light receiving surface of wafer 5 is textured as shown by texture line 10. Wafer 5 has a first passivation layer on the front surface made of a layer of silicon nitride 15. Photovoltaic cell 1 has a second passivation layer 25 of silicon nitride and is positioned in contact with wafer 5. Cell 1 has first electrical contact 30 comprising a layer portion 33 and point contacts 35. (Only one point contact 35 is shown for clarity.) First electrical contact 30 comprises, for example, a metal such as tin, or tin alloyed with antimony, phosphorus, or a combination thereof. Cell 1 has an insulation layer 40 comprising, for example, silicon nitride electrically separating second electrical contact 45 from first electrical contact 30. Second electrical contact 45 comprises a layer portion 48 and point contacts 50. Second electrical contact comprises, for example, a metal such as aluminum. For clarity, only one point contact 50 is shown in FIG. 1. FIG. 1, shows how the insulation layer 40 separates and electrically insulates electrical contact layer 30 from layer 45 and, at 42, shows how the insulation layer extends around point contact 50 thereby electrically insulating point contact 50 from first contact 30. The thickness of the insulation layer 42 in this and other embodiments of this invention can be up to about 100 microns, for example, about 5 microns thick up to about 100 microns thick. FIG. 1 also shows indentations or depressions 60 in second contact 45. Such depressions, which can be crater-like in appearance, are formed by laser firing contact layer 48 to form point contacts 50. The laser firing process to form such point contacts will be described in more detail below. FIG. 1 also shows a region 65 along the edge of cell 1 where the first electrical contact layer 30 is exposed so that an electrical connection can be made to such electrical contact. Such electrical connection may be in the form of a bus bar soldered to or otherwise electrically connected to layer 30.

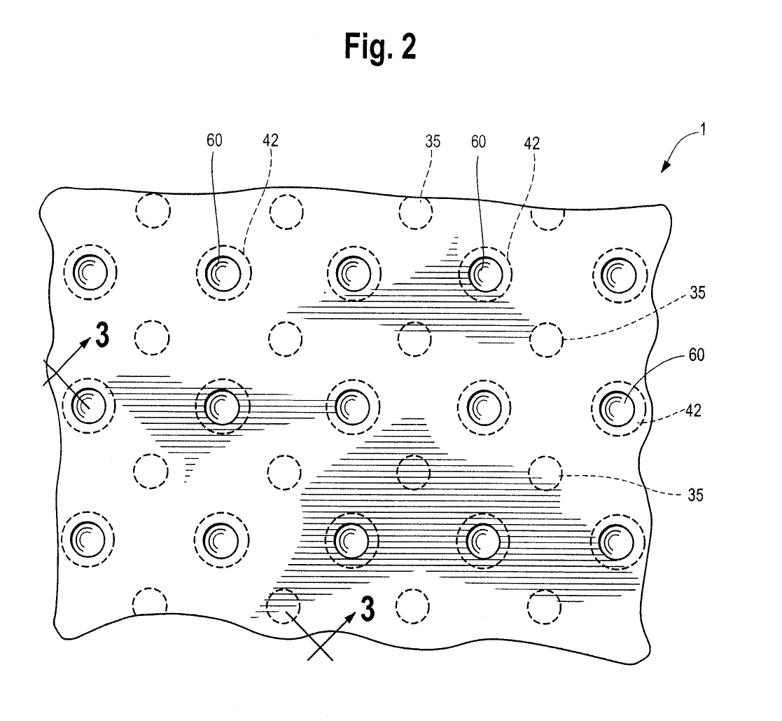

FIG. 2 is a plan view of part of the same photovoltaic cell shown in FIG. 1 looking onto the back surface of the photovoltaic cell. Components shown in FIG. 2 that are the same as those shown in FIG. 1 are numbered the same. FIG. 2 shows that the point contacts can be in the form of an array pattern on the back of the photovoltaic cell. FIG. 2 shows depressions 60 (only a few numbered for clarity) and it also shows, as broken lines, the point contacts 35 that extend from the first electrical contact layer 30 to the wafer. The outer dotted sections 42 (only a few numbered for clarity) show the perimeter of the insulation layer 42 that is around point contacts 50.

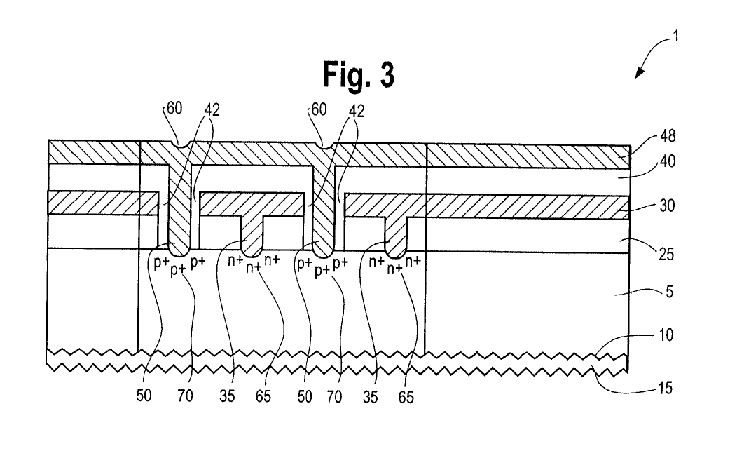

FIG. 3 shows a cross section view of a photovoltaic cell shown in FIG. 2. The cross section is shown as 3 in FIG. 2. All components of cell 1 in FIG. 3 that correspond to the same components in FIGS. 1 and 2 are numbered the same.

FIG. 3 also shows n⁺ emitter region 65, depicted as a series of “n⁺”, located where point contacts 35 of first electrical point contacts 30 meet or enter wafer 5. FIG. 3 also shows as a series of p⁺ base or ohmic contact regions 70 where point contacts 50 of second electrical contact 45 meet or enter wafer 5. The p⁺ regions can also act as a back surface field (BSF) region. These point contact regions can, as will be discussed in more detail below, be formed, for example by a laser firing process to form the point contacts. The symbols “p⁺” and “n⁺” are used to denote high concentrations of the p-type and n-type dopants, respectively in the silicon in those regions.

Without intending to be bound by a theory of operation, in the embodiment of the invention shown in FIGS. 1 through 3 where the wafer is a p-type wafer and the first electrical contact and corresponding point contacts are n-type (and form n⁺ regions where the point contacts meet the wafer), and the second electrical contact and corresponding point contacts are p-type (and form p⁺ regions where the point contacts meet the wafer), the point contacts 35 that are part of the first electrical contact collect photogenerated electrons and the second electrical contact point contacts 50 collect photogenerated holes. The photogenerated electrons and holes are created when light is incident on the front surface 10 and is absorbed in the crystalline silicon wafer 5. A p-n junction with its built-in electric field is formed at the interface of the n-type point contacts 35 and the wafer that helps to collect the photogenerated electrons. The point contacts 50 form an ohmic contact to the p-type wafer 5 that efficiently collects the photogenerated holes. In an alternative embodiment, the first electrical contact as shown in FIGS. 1 through 3 can have a p-type conductivity and the second electrical contact n-type conductivity. Similarly, if the wafer has an n-type conductivity, the first electrical contact and corresponding point contacts can be of n-type or p-type conductivity and the second electrical contact and its corresponding point contacts will have a conductivity opposite the conductivity of the first electrical contact.

As described above, the electrical contacts in the photovoltaic cells of this invention can comprise a layer of metal or alloyed metal and comprise point contacts extending from the metal a layer to the semiconductor wafer. The metal layers can have a thickness of about 0.5 to about 10.0 microns, preferably, about 1.0 to about 3.0 microns. Preferably, the thickness of the metal layers is selected to eliminate any significant series resistance in the photovoltaic cell.

The point contacts for each layer can be in any suitable pattern across the back surface of the cell such as in rows and columns. However, preferably they are in a pattern of equally spaced rows and columns as shown, for example, in FIG. 2. Preferably the emitter point contacts having an n⁺ contact region to a p-type wafer (or the p⁺ contacts to an n-type wafer) are spaced so that the distance between the emitter point contacts are less than the minority carrier diffusion length. Thus, for a minority carrier diffusion length of 500 microns, the spacing between emitter point contacts would be about 250 microns apart or less as measured from the center of one point contact to the center of the other. For example, the number of point contacts for each electrical contact can be about 10² to about 10⁴ per square cm of cell surface. Preferably, the size and spacing of the point contacts having ohmic regions to the base material (for example, the p⁺ contacts to a p-type wafer) are adjusted to minimize the series resistance of the solar cell and to maximize the cell performance.

Although the point contacts are shown in the Figures as cylindrically shaped shafts or columns having a circular horizontal cross-sectional shape, it is to be understood that such point contacts can be any suitable shape. For example, instead of cylindrically shaped shafts or columns having a circular horizontal cross-sectional shape, such point contacts can be hemispherical, or shafts or columns with an oval or more elongated cross-sectional shape, or any other suitable geometric shape or pattern. They can be in the form of lines. The width of the point contact, for example, the diameter of a cylindrically or column-shaped point contact, or the width of a point contact having an oval or more elongated cross-sectional shape, can be up to about 100 microns, for example, about 5 to about 100 microns. The point contacts as shown in the Figures have a sufficient length to extend from the metal layer to which they are attached into the surface of the wafer. They can extend from the surface into the wafer about 1 to about 10 microns.

The point contacts can be formed by any suitable means for forming the structures as described herein for such point contacts. For example, they can be formed by first forming an opening or hole of a desired diameter into the layer or layers through which the point contact passes, followed by filling such hole or opening with the material, such as the metal, used for the contact. Such hole or opening can have a diameter or width of about 5 to about 100 microns corresponding to the diameter or width of the point contact. The hole or opening can be made by any suitable method such as by mechanical drilling or by using a photolithographic masking and etching process, or by ablating the material using a laser, such as an excimer laser or a Nd-YAG laser having a laser beam density sufficient to ablate or remove the layer or layers, through which the point contact passes. If a laser is used to form the hole or opening, the surface of the wafer, if exposed and damaged by the laser can be treated by, for example, a hydrogen plasma or by atomic hydrogen, to remove or cure the laser damaged regions of the wafer and to passivate any remaining defects. When the point contact is formed by a method where a hole or opening in the passivation layer (for example, silicon nitride) is filled with the contact material, it is desirable to use a rapid thermal annealing process to cause the formation of a heavily doped region or layer adjacent to where the point contact meets the wafer. This emitter or ohmic contact region or layer is a region or layer of the wafer that is doped by the components that form the point contact. For example, when the point contact comprises aluminum, the emitter region in an n-type wafer will be doped with aluminum. The amount of p-type doping and the depth of the doped layer or region is controlled mainly by the time and temperature of the heat treatment. Formation of such emitter and base regions by rapid thermal annealing can be accomplished by, for example, heating the contact layers to a high temperature and for a sufficient time to form the desired contact regions. For example a temperature of about of 800° C. to about 1000° C. for about 5 seconds to about 2 minutes. In the case of aluminum, for example, one minute at about 900° C. Another, more preferred method for forming the point contacts and corresponding emitter and ohmic regions for the photovoltaic cells of this invention, is to use a firing process using, for example, a laser. In the laser firing process, the surface of the material used for the contact, such as a layer of metal, is heated using a laser beam. The heated material such as a metal melts through the underlying layers and into the wafer. The hot metal or other material also forms the emitter or ohmic contact region, as described above, when it contacts the wafer. The laser firing process can be performed using a Q-switched, Nd-YAG laser with a pulse duration of, for example, about 10 to 100 nanoseconds (ns). In addition to using a laser, such firing process to form the point contacts can be accomplished using, for example, electron or ion beam bombardment to heat the contact material and form the fired contact.

An insulation layer that is positioned between the first and the second contacts that electrically separates the contacts can have a thickness of about 70 to about 2000 nm. As mentioned above, such insulation layer can comprise one or more of silicon nitride, silicon oxynitride or silicon dioxide. It can comprise some other suitable dielectric material. This insulation layer should be free of pinholes so that there is no significant leakage between the first and second contact layers.

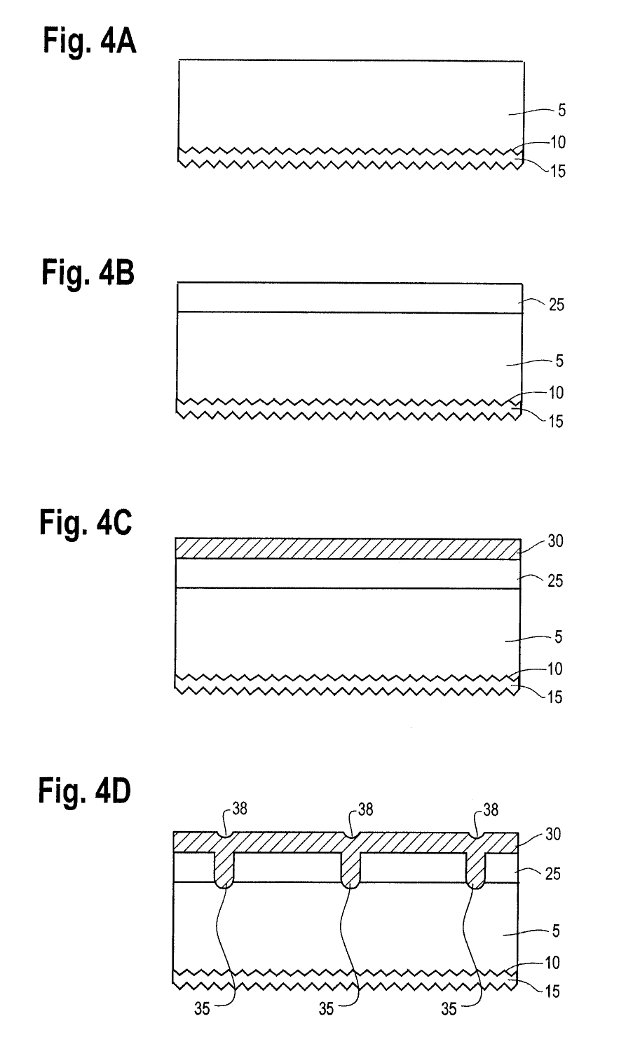

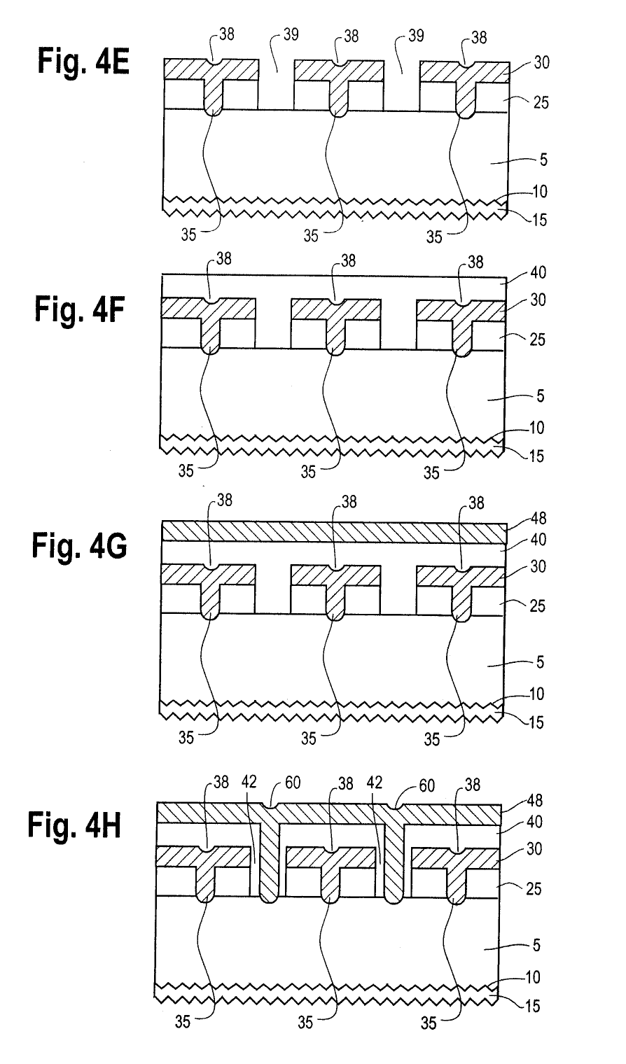

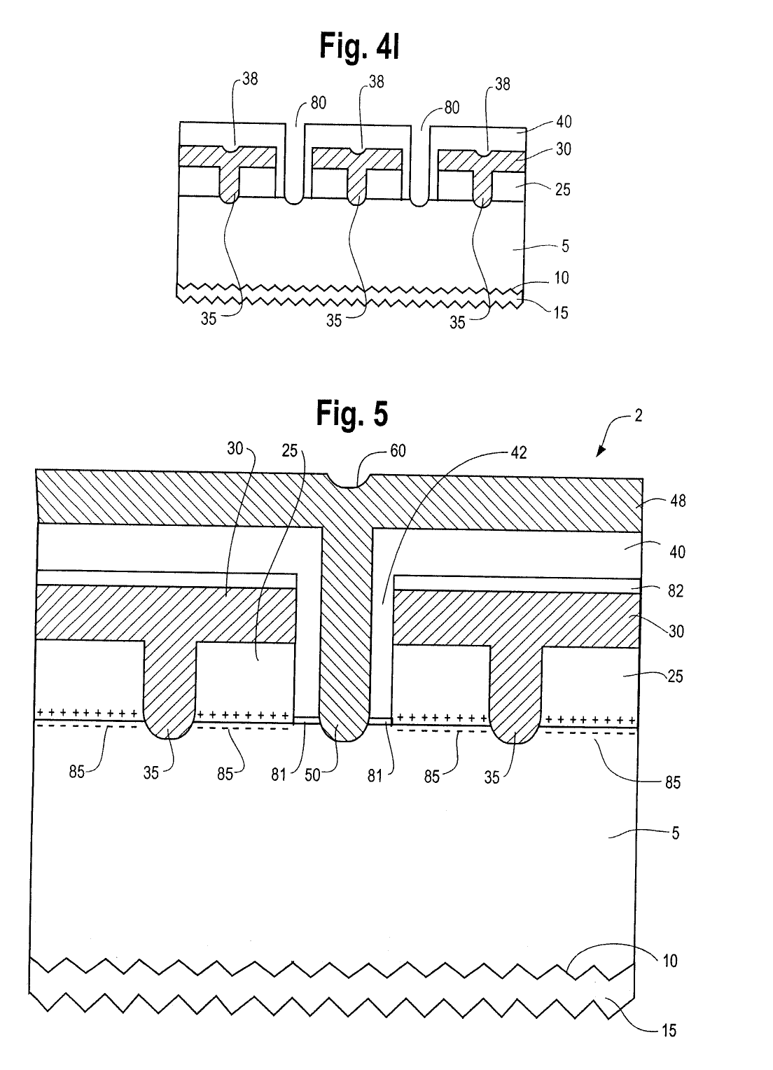

A process for manufacturing a photovoltaic cell in accordance with this invention and having a structure as shown in FIGS. 1 through 3 will now be described, it being understood that this is not the only process for preparing such photovoltaic cell. The process is described with reference to FIG. 4. The elements numbered in FIG. 4 that are the same as in FIGS. 1-3 are numbered the same.

The process starts with a textured, a p-type silicon wafer 5 having layer 15 of, for example, silicon nitride on the surface of the wafer that will become the light receiving side of the photovoltaic cell. As described above, this layer functions as an antireflective coating as well as a surface passivation layer. This wafer is shown in FIG. 4A. In the next step, as shown in FIG. 4B, a second passivation layer of, for example, silicon nitride 25 is deposited by PECVD on the second side of the wafer, directly on the wafer surface. In the next step as shown in FIG. 4C a first metal contact layer 30 comprising, for example, tin alloyed with antimony is added by magnetron sputtering. In the next step, as shown in FIG. 4D, a plurality of laser fired contacts 35 are formed in the metal layer 30 by directing a laser beam from, for example, a Nd-YAG laser, on the outer surface of metal layer 30. The laser heats the metal layer in a spot and causes the metal layer to melt in the region where the laser is positioned on the metal layer. The process is conducted so that the heated metal melts through the layer 25 and into the silicon wafer to form the laser fired contacts 35. As shown in FIG. 4D, indentations or depressions 38, which can be crater-like in appearance, are formed on the surface of the metal layer 30 where the laser beam was positioned to form the laser fired contact. In the next step in the process as shown in FIG. 4E, a plurality of holes or openings 39 are made at least through the metal layer 30 and, preferably through the passivation layer 25, as shown in FIG. 4E, all the way to the wafer. In processing cells of this invention, such holes or openings can be any suitable shape. Preferably they are round although they can be, for example, oval or elongated, e.g., linear, in shape. The diameter or width of such holes or openings can be about 5 to about 100 microns. In the next step of the process as shown in FIG. 4F, an insulation layer 40 of, for example, silicon nitride is deposited on first metal contact layer 30 using PECVD. This insulation layer fills the holes or openings 39. In the next step, as shown in FIG. 4G, a second metal contact layer 48 of, for example, aluminum is deposited on the insulation layer 40 by sputtering. In the next step, as shown in FIG. 4H, a plurality of laser fired contacts 50 are formed in the metal layer 48 by directing a laser beam from, for example, a Nd-YAG laser, on the outer surface of metal layer 48. The laser heats the metal layer in a spot and causes the metal layer to melt in the region where the laser is positioned on the metal layer. The process is conducted so that the heated metal melts through insulation layer 40 that was deposited in openings 39 and into the silicon wafer to form the laser fired contacts 50. The process of heating metal layer 48 is conducted so that as the heated metal melts through insulation layer 40, a region 42 of insulation layer 40 remains around point contact 50 thereby electrically insulating point contact 50. FIG. 4H shows the completed cell having both electrical contacts on the back side of the wafer, each electrical contact having point contacts with the silicon wafer. In alternate processing steps, not shown in FIG. 4, rather than fire the contacts through the first passivation layer and the insulation layer, holes or openings can be formed in the second passivation layer and in the insulation layer and, when the metal layers are deposited, the metal will fill the holes or openings to form the point contacts. For example, with reference to FIG. 4F, holes or openings would be made in layer 40 in the region where insulation layer 40 filled holes 39. This is shown in FIG. 4I where holes or openings 80 are formed through the insulation layer 40 and preferably down to and even into the wafer 5 as shown in FIG. 4I. Then, when metal layer 48 is deposited, the metal will fill the holes 80 to form point contacts 50 with wafer 5. A rapid thermal annealing process is subsequently used to diffuse the dopants from the metal layer 48 into the wafer to form the heavily doped emitter or base contact regions.

FIG. 5 shows another preferred embodiment of the invention where the photovoltaic cell 2 has buffer layer 81 of, for example, boron-doped a-Si:H, positioned around point contact 50 and between the silicon wafer 5 and the insulating layer 42. This buffer layer can have a thickness of up to about 40 nm, for example, about 3 nm to about 40 nm. All of the elements in FIG. 5 that are numbered the same as the elements shown in FIGS. 1 through 4 are numbered the same.

FIG. 5 shows buffer layer 81 of, for example, boron-doped a-Si:H (or a layer of undoped a-Si:H and a layer of boron-doped a-Si:H) positioned near point contact 50 and between insulation area 42 and wafer 5. For reasons that will be described below, photovoltaic cell 2 shown in FIG. 5 has a layer 82 on top of contact layer 30. FIG. 5 also shows an inversion layer 85 which is designated as a series of “−” in the p-type wafer 5. While not intending to be bound by any theory, it is believed that the positive charges denoted by a series of “+” in the silicon nitride layer 25 can form such inversion layer that will assist in the collection of minority carriers. The buffer layer 81 of material such as boron-doped a-Si:H, serves to prevent an inversion layer from forming near the point contact 50. If such layer 81 were not present, minority carriers could leak to the point contact 50 through the inversion layer and cause shunting in the photovoltaic cell.

A photovoltaic cell having the structure as shown in FIG. 5 can be made by adding an extra step to the process shown in FIG. 4. Specifically, after the step in the process as shown in FIG. 4E, a layer of, for example, boron-doped a-Si:H is deposited (or a layer of undoped a-Si:H and a layer of boron-doped a-Si:H), and such layer forms in the openings 39 to form layer 81 and also layer 82 on layer 30. Thereafter, the rest of the process is the same. Forming the photovoltaic cell using such processing steps will produce the structure as shown in FIG. 5. The layer of boron-doped a-Si:H can be deposited by one or more of the methods described above for forming a-Si:H and adding, for example, B₂H₆ as a dopant gas. The thickness of the boron-doped layer can be up to about 30 nm for example, about 5 to about 30 nm, and the amount of dopant is suitably selected to minimize any current leakage that might otherwise occur between the inversion layer and the point contacts 50; thus the thickness of the boron-doped layer and the concentration of boron in the layer is preferably adjusted to prevent a significant amount of band bending occurring in the silicon layer next to layer 81. If a combination of a boron-doped layer and a layer of a-Si:H is used, the a-Si:H can have a thickness up to about 30 nm, for example, about 3 to about 30 nm, and the thickness of and concentration of boron in the boron-doped layer would be suitably selected to minimize the aforementioned current leakage. In addition to a-Si:H, other materials such as microcrystalline silicon or hydrogenated amorphous silicon alloyed with carbon or hydrogenated amorphous silicon doped with boron or phosphorus such as those described above, and one or more mixtures thereof, could also be used as a buffer layer 81 to prevent the formation of an inversion layer near the point contact 50.

When referring herein to a layer positioned over another layer or over a wafer, it does not necessarily mean that such layer is positioned directly on and in contact with such other layer or wafer. Layers of other materials may be present between such layers or between such layer and the wafer.

Unless specified otherwise herein, silicon nitride preferably means hydrogenated silicon nitride. For example it can have about 5 to about 20 atomic percent hydrogen. Such silicon nitride can be formed by PECVD. Such silicon nitride formed by PECVD typically has a stoichiometry that is close to Si₃N₄. Methods for depositing layers of a-Si:H, with or without dopants such as phosphorus or boron, or other elements such as nitrogen or carbon, are well know in the art. However, general conditions for depositing such layers by PECVD, using a mixture of silane in hydrogen are substrate temperatures of about 100° C. to about 250° C., and pressures of about 0.05 to about 5 Torr. Methods for depositing layers of silicon nitride are also well known. However, general conditions for depositing such layers by PECVD using a mixture of silane and ammonia are substrate temperatures of about 200° C. to about 450° C., and pressures of about 0.05 to about 2 Torr.

The photovoltaic cells of this invention have high efficiency in converting light energy into electrical energy. Photovoltaic cells of this invention made using a monocrystalline silicon wafer, preferably of an area of about 100 to about 250 square centimeters, can have an efficiency of at least about 20%, and can have efficiency of up to or of at least about 23%. As used herein, the efficiency of the photovoltaic cells made by the process of this invention is measured using the standard test conditions of AM 1.5 G at 25° C. using 1000 W/m² (1000 watts per square meter) illumination where the efficiency is the electrical energy output of the cell over the light energy input, expressed as a percent.

The photovoltaic cells of this invention can be used to form modules where, for example, a plurality of such cells are electrically connected in a desired arrangement and mounted on or between a suitable supporting substrate such as a section of glass or other suitable material. Methods for making modules from photovoltaic cells are well known to those of skill in the art.

It is to be understood that only certain embodiments of the invention have been described and set forth herein. Alternative embodiments and various modifications will be apparent from the above description to those of skill in the art. These and other alternatives are considered equivalents and within the spirit and scope of the invention.

U.S. patent application Ser. No. 11/565,738, filed on Dec. 1, 2006, is incorporated by reference herein in its entirety.

Having described the invention, that which is claimed is:

1. A photovoltaic cell comprising:
a wafer comprising a semiconductor material of a first conductivity type, the wafer comprising a first light receiving surface and a second surface opposite the first surface;
a first passivation layer positioned over the first surface of the wafer;
a second passivation layer positioned over the second surface of the wafer;
a first electrical contact comprising point contacts positioned over the second surface of the wafer and having a conductivity opposite to that of the wafer;
a second electrical contact comprising point contacts and positioned over the second surface of the wafer and separated electrically from the first electrical contact.

2. The photovoltaic cell of claim 1 wherein the semiconductor wafer comprises doped crystalline or multi-crystalline silicon.

3. The photovoltaic cell of claim 2 wherein the first passivation layer comprises silicon nitride, hydrogenated amorphous silicon, hydrogenated microcrystalline silicon or a combination thereof.

4. The photovoltaic cell of claim 3 wherein the first passivation layer comprises silicon nitride.

5. The photovoltaic cell of claim 1 comprising emitter regions adjacent the point contacts of an electrical contact where the point contacts enter the surface of the wafer.

6. The photovoltaic cell of claim 1 comprising ohmic regions adjacent the point contacts of an electrical contact where the point contacts enter the surface of the wafer.

7. The photovoltaic cell of claim 1 comprising an inversion layer electrically isolated from the point contacts of the second electrical contact.

8. The photovoltaic cell of claim 1 wherein the point contacts are formed by laser firing.

9. The photovoltaic cell of claim 1 wherein one of the contacts comprises one or more of antimony, phosphorus, or a combination thereof.

10. The photovoltaic cell of claim 1 wherein the wafer has a diffusion length and the ratio of the diffusion length to the thickness of the wafer is greater than 1.1.

11. A process for making a photovoltaic cell from a semiconductor wafer of a first conductivity type and having a first, light receiving surface and a second surface opposite the first surface comprising:
forming a first passivation layer positioned over the first surface of the wafer;
forming a second passivation layer positioned over the second surface of the wafer;
forming a first layer of electrical contact material over the second passivation layer;
forming a plurality of point contacts from the first layer of electrical contact material through the second passivation layer and into the wafer;
forming a plurality of openings in the first layer of electrical contact material and through the second passivation layer;
forming a layer of insulation material over the first layer of electrical contact material and into the plurality of openings to form filled openings;
forming a second layer of electrical contact material over the layer of insulation material,
forming a plurality of point contacts from the second layer of electrical contact material through the filled openings and into the wafer.

12. The process of claim 11 wherein the point contacts are formed by laser firing.

13. The process of claim 1 wherein the first and second passivation layers comprise silicon nitride.

14. The process of claim 1 wherein one of the electrical contacts comprises tin.

15. The process of claim 1 wherein the semiconductor wafer comprises doped crystalline silicon or multi-crystalline silicon.

16. The photovoltaic cell of claim 9 wherein the antimony, phosphorus or combination thereof is alloyed with tin.

17. The photovoltaic cell of claim 1 wherein one of the contacts comprises antimony.
